(19) United States
(12) Patent Application Publication
(10) Pub. No.: US 2015/0280073 A1
(43) Pub. Date: Oct. 1, 2015

(54) SEMICONDUCTOR LIGHT-EMITTING ELEMENT AND PRODUCTION METHOD THEREFOR

(71) Applicant: USHIO DENKI KABUSHIKI KAISHA, Tokyo (JP)

(72) Inventor: Kohei MIYOSHI, Himeji-shi (JP)

(73) Assignee: USHIO DENKI KABUSHIKI KAISHA, Tokyo (JP)

(21) Appl. No.: 14/667,046

(22) Filed: Mar. 24, 2015

(30) Foreign Application Priority Data
Mar. 27, 2014 (JP) 2014-067117

(51) Int. Cl. H01L 33/40; H01L 33/54

(52) U.S. Cl. CPC H01L 33/405; H01L 33/54; H01L 2933/0016; H01L 2933/0058; H01L 2933/005

(57) ABSTRACT

An object is to realize a semiconductor light-emitting element having further increased light extraction efficiency than before, and a production method therefor. The method for producing a semiconductor light-emitting element of the present invention includes: a step (a) of preparing a substrate; a step (b) of forming a first semiconductor layer, an active layer and a second semiconductor layer on the upper layer of the substrate in this order from below; a step (c) of forming a first conductive layer constituting a reflective electrode on the upper layer of the second semiconductor layer; a step (d) of forming a second conductive layer, without previously conducting annealing, constituting a first protective layer in a thickness of equal to or less than 7 nm on an upper surface of the first conductive layer after the step (c); and a step (e) of conducting annealing after the step (d).

### BACKGROUND OF THE INVENTION

1. Field of the Invention

The present invention relates to a semiconductor light-emitting element having, on the upper layer of a substrate, an n-type semiconductor layer, a p-type semiconductor layer, and a light-emitting layer formed therebetween. The present invention also relates to a method for producing such a semiconductor light-emitting element.

2. Description of the Related Art

As a conventional semiconductor light-emitting element, for example, the structure described in Patent Document 1 is disclosed.

FIG. 10 schematically shows a sectional view of the semiconductor light-emitting element disclosed in Patent Document 1. A conventional semiconductor light-emitting element 90 includes, on a support substrate 91, a conductive layer 92, a reflective film 93, an insulating layer 94, a reflective electrode 95, a semiconductor layer 99, and an n-side electrode 100. The semiconductor layer 99 is made up of a p-type semiconductor layer 96, an active layer 97, and an n-type semiconductor layer 98 sequentially laminated from the side of the support substrate 91.

The insulating layer 94 is formed in a region containing a position vertically below the position where the n-side electrode 100 is formed. While the reflective film 93 made of a metal material is formed under the insulating layer 94, the reflective film 93 does not have ohmic property and does not function as an electrode. On the other hand, the reflective electrode 95 is made of a metal material, and functions as an electrode (p-side electrode) because ohmic contact with the p-type semiconductor layer 96 is achieved.

The reflective electrode 95 is intended to increase light extraction efficiency by reflecting the light radiated in the direction toward the support substrate 91 (downward direction in the drawing) among light emitted by the active layer 97 to extract the light on the side of the n-side semiconductor layer 98 (upward direction in the drawing). The reflective film 93 is also formed for a similar purpose, and the reflective film 93 reflects the light having passed through the part where the reflective electrode 95 is not formed and having travelled downward, to change the traveling direction to the side of the n-side semiconductor layer 98, so that the light extraction efficiency increases.

### PRIOR ART DOCUMENT

### Patent Document

Patent Document 1: Japanese Patent No. 4207781

### BRIEF SUMMARY OF THE INVENTION

### Problem to be Solved by the Invention

The semiconductor light-emitting element 90 shown in FIG. 10 is produced in the following manner. First, the semiconductor layer 99 is formed on a substrate. Then, an electrode material constituting the reflective electrode 95 is vapor deposited on the upper surface of the semiconductor layer 99, and an annealing treatment at a high temperature of, for example, about 400° C. to 600° C. is conducted so as to obtain ohmic contact between the electrode material and the semiconductor layer 99 (more specifically, the p-type semiconductor layer 96). After sequentially laminating the insulating layer 94, the reflective film 93, and the conductive layer 92, the support substrate 91 is bonded from the side of the conductive layer 92, and the substrate on which the semiconductor layer 99 grows is exfoliated.

A metal material is used for the material of the reflective electrode 95. Metal and a semiconductor have different work functions, and the difference in energy level is generated in the contact interface to cause a barrier. Such a barrier makes the current difficult to flow, then the operation voltage increases. Therefore, in an element wherein substances having different work functions, such as metal and a semiconductor, contact each other to forma barrier, it is necessary to conduct an annealing treatment at high temperature as described above in order to reduce the barrier of both energy levels and decrease the contact resistance between the reflective electrode 95 and the semiconductor layer 99.

As described above, the reflective electrode 95 is intended to increase light extraction efficiency by reflecting, on the side of the n-side semiconductor layer 98, the light radiated in the direction toward the support substrate 91 among light emitted by the active layer 97. Therefore, the reflective electrode 95 preferably made of a material having high light reflectance, for example, Ag. However, it has been found that a large number of voids are generated in a surface of the reflective electrode 95, especially between the reflective electrode 95 and the semiconductor layer 99 when the semiconductor light-emitting element 90 is produced by the method as described above.

FIG. 11 is a photograph taken through the substrate on which the semiconductor layer 99 is allowed to grow from the side of the light extraction (above the n-type semiconductor layer 98 in FIG. 10), after the electrode material constituting the reflective electrode 95 is vapor deposited on the upper surface of the semiconductor layer 99 and the annealing treatment is conducted, in production of the semiconductor light-emitting element 90 by the method as described above. As can be seen in the photograph of FIG. 11, a large number of black spots originating from voids 101 appear on a surface of the reflective electrode 95. In particular, a very large number of voids 101 are observed in the vicinity of the interface between the semiconductor layer 99 and the reflective electrode 95. Generation of such a large number of voids 101 in the surface of the reflective electrode 95 decreases the light reflectance on the reflective electrode 95, and hence deteriorates the light extraction efficiency.

In light of the aforementioned problems, an object of the present invention is to provide a semiconductor light-emitting element having further increased light extraction efficiency than before, and a production method therefor.

### Means for Solving the Problem

The present invention provides a method for producing a semiconductor light-emitting element having a first semiconductor layer of n-type or p-type, a second semiconductor layer of a conductivity type different from a conductivity type of the first semiconductor layer, and an active layer formed between the first semiconductor layer and the second semiconductor layer, the method comprising:

a step (a) of preparing a substrate;

a step (b) of forming the first semiconductor layer, the light-emitting layer and the second semiconductor layer on the upper layer of the substrate in this order from below;

a step (c) of forming a first conductive layer constituting a reflective electrode on the upper layer of the second semiconductor layer;

a step (d) of forming a second conductive layer, without previously conducting annealing, constituting a first protective layer in a thickness of equal to or less than 7 nm on an upper surface of the first conductive layer after the step (c); and

a step (e) of conducting annealing after the step (d).

The present inventor has conducted diligent studies, and made inference that the large number of voids appearing in the surface of the reflective electrode of a semiconductor light-emitting element made by the conventional production method are caused by the following reason, that is, the electrode material aggregates while annealing at high temperature is carried out after an electrode material constituting the reflective electrode is vapor-deposited. Thus, in the above method, after the first conductive layer constituting the reflective electrode is vapor-deposited, the second conductive layer constituting the first protective layer is vapor deposited on the upper surface of the first conductive layer without previously annealing, and then annealing is carried out. This annealing is conducted for achieving ohmic contact between the first conductive layer and the second semiconductor layer.

According to this method, since the second conductive layer is formed on the upper surface of the first conductive layer and the region where the second conductive layer is exposed is small at the time of annealing, the phenomenon can be suppressed where the material constituting the first conductive layer aggregates during annealing. As a result, as will be described later in the section of “DETAILED DESCRIPTION OF THE INVENTION”, formation of voids is greatly suppressed in a surface of a reflective electrode of a semiconductor light-emitting element produced by this method, and light extraction efficiency is increased.

Particularly in the step (d), it is preferred to form the second conductive layer on the whole upper surface of the first conductive layer. This makes it possible to greatly suppress the phenomenon where the material constituting the first conductive layer aggregates during annealing, because the second conductive layer is not exposed at the time of annealing.

Further, the present inventor has produced a semiconductor light-emitting element while appropriately changing the thickness of the second conductive layer constituting the first protective layer, and made the element to emit light. It has been proved that when the thickness of the second conductive layer is equal to or larger than a predetermined value, the emission intensity increases in a predetermined region of the light-emitting element, but the emission intensity decreases in another region, in other words, distribution of emission intensity occurs depending on the region. The present inventor has finally found that the uniformity of the distribution of emission intensity can be enhanced by adjusting the thickness of the second conductive layer to less than 10 nm, more specifically, equal to or less than 7 nm.

The reason why the distribution of emission intensity occurs depending on the position when the thickness of the second conductive layer is increased is not clear at present, but the present inventor has made inference as follows.

As described above, the second conductive layer is provided for suppressing formation of voids between the first conductive layer (i.e., reflective electrode) and the second semiconductor layer. However, when annealing is conducted after forming the second conductive layer as a thick film, voids are formed between the second conductive layer and the first conductive layer, and the presence of the voids interferes the current flow to the active layer.

In the state immediately after vapor deposition of the second conductive layer, the voids are not formed in the vicinity of the interface between the first conductive layer and the second conductive layer. It is however conceivable as follows: by conducting annealing subsequently, the surface of the first conductive layer moves by heat and fine irregularities are formed, while the second conductive layer formed on the upper surface thereof cannot follow the irregularities, and as a result, a void is formed above a recess formed by the first conductive layer. This is also attributable to the fact that the first conductive layer is made of a material constituting the reflective electrode and has property of easily moving under heat application.

As will be described later in the section of “DETAILED DESCRIPTION OF THE INVENTION”, when the second conductive layer is formed as a thin film having a thickness of equal to or less than 7 nm, high emission intensity is exhibited from almost the whole surface of the light-emitting element, and the uniformity of the distribution of emission intensity increases. One reason for this is inferred that by forming the second conductive layer as a thin film, the second conductive layer is formed partly in the form of islands rather than the perfect film on the upper surface of the first conductive layer. It is conceivable that by forming the second conductive layer in the form of islands, even if the surface of the first conductive layer moves during annealing, the second conductive layer can follow the movement of the first conductive layer, and the first conductive layer closely adheres to the upper surface of the second conductive layer.

That is, according to the above method, formation of voids not only between the second semiconductor layer and the first conductive layer but also between the first conductive layer and the second conductive layer is suppressed. Therefore, a semiconductor light-emitting element is realized which has further increased emission intensity than before and is capable of exhibiting increased emission intensity throughout the whole surface of the element.

A metal material containing Ag can be used for the material of the first conductive layer. Thus, a semiconductor light-emitting element having a reflective electrode exhibiting high reflectance can be produced.

A metal material containing Ni can be used for the material of the second conductive layer. When Ni is used for the first conductive layer, it is possible to keep high reflectance possessed by Ag while ensuring high adhesion with Ag constituting the first conductive layer.

It is conceivable that by conducting annealing after vapor deposition of the second conductive layer made of a metal material containing Ni, the second conductive layer is oxidized partly or wholly, and an oxide layer of the metal material containing Ni may be formed. However, the oxide layer still has conductivity, and will not interfere injection of the current into the active layer.

In addition to the above method, a step (f) of forming, after the step (e), a conductive second protective layer on the upper layer of or directly on the second conductive layer may be provided.

In the case that the second protective layer is formed above the second conductive layer, a conductive layer intended to function as a reflective layer may be formed between the second conductive layer (this corresponds to “first protective layer”) and the second protective layer.

The second protective layer may have a multi-layered structure laminating a layer containing Ni, a layer containing Ti and a layer containing Pt. The layer containing Ti and the layer containing Pt are provided for the purpose of preventing a material of a solder layer from diffusing into the first conductive layer (i.e., reflective electrode) to deteriorate the reflectance when the solder layer is formed later. The layer containing Ni is provided for the purpose of preventing a layer containing Ti constituting the second protective layer from diffusing into the first conductive layer (i.e., reflective electrode) to deteriorate the reflectance.

In the step (e), annealing is preferably conducted at temperature at which ohmic contact is achieved between the first conductive layer and the second semiconductor layer. By setting the annealing temperature particularly to equal to or higher than 350° C. and equal to or lower than 550° C., it is possible to suppress generation of voids while achieving ohmic contact between the first conductive layer and the second semiconductor layer.

The thickness of the first conductive layer can be, for example, equal to or less than 150 nm. From the viewpoint of preventing formation of voids in the surface of the reflective electrode, it is also conceivable to form a thick film having a thickness in the order of micrometers. However, when the reflective electrode is formed as a thick film, the vapor deposition step takes quite some time, and not only other processes are hindered, but also the problem of ensuring the flatness arises because of a difference in level relative to the peripheral part. According to the aforementioned method, even when the reflective electrode is formed as a thin film having a thickness of equal to or less than 150 nm, formation of voids in the surface is suppressed.

Also, the present invention provides a semiconductor light-emitting element having, on the upper layer of a substrate, a first semiconductor layer of n-type or p-type, a second semiconductor layer of a conductivity type different from a conductivity type of the first semiconductor layer, and an active layer formed between the first semiconductor layer and the second semiconductor layer, the semiconductor light-emitting element comprising:
a reflective electrode formed on a surface of a side opposite to a side where the active layer is formed among surfaces of the second semiconductor layer, and

a first protective layer formed on a surface of a side opposite to a side where the second semiconductor layer is formed among surface of the reflective electrode, the first protective layer having a thickness of equal to or less than 7 nm and containing a conductive oxide of a metal material different from a material of the reflective electrode.

In the above configuration, the first protective layer may be formed on the whole upper surface of the reflective electrode.

In the above configuration, the reflective electrode may be made of a metal material containing Ag, and the first protective layer may be a layer having an oxide of a metal material containing Ni.

In addition to the above configuration, the semiconductor light-emitting element may have a second protective layer which is formed on a surface of a side opposite to a side where the reflective electrode is formed among surfaces of the first protective layer, or at a position farther from the first protective layer than the surface, and which is made of a metal material different from a material of the reflective electrode. In particular, in the latter case, a conductive reflective layer may further be formed between the second protective layer and the first protective layer.

The second protective layer may have a multi-layered structure laminating a layer containing Ni, a layer containing Ti and a layer containing Pt, or may have a multi-layered structure laminating a layer containing Ti and a layer containing Pt.

### Effect of the Invention

According to the present invention, a semiconductor light-emitting element having further increased light extraction efficiency than before is realized.

### BRIEF DESCRIPTION OF THE DRAWINGS

FIG. 1 is a sectional view schematically showing a configuration of a first embodiment of a semiconductor light-emitting element;

FIG. 2A is a part of a sectional view showing a process of the first embodiment of the semiconductor light-emitting element;

FIG. 2B is apart of a sectional view showing the process of the first embodiment of the semiconductor light-emitting element;

FIG. 2C is a part of a sectional view showing the process of the first embodiment of the semiconductor light-emitting element;

FIG. 2D is a part of a sectional view showing the process of the first embodiment of the semiconductor light-emitting element;

FIG. 2E is a part of a sectional view showing the process of the first embodiment of the semiconductor light-emitting element;

FIG. 2F is a part of a sectional view showing the process of the first embodiment of the semiconductor light-emitting element;

FIG. 2G is a part of a sectional view showing the process of the first embodiment of the semiconductor light-emitting element;

FIG. 2H is a part of a sectional view showing the process of the first embodiment of the semiconductor light-emitting element;

FIG. 2I is a part of a sectional view showing the process of the first embodiment of the semiconductor light-emitting element;

FIG. 2J is a part of a sectional view showing the process of the first embodiment of the semiconductor light-emitting element;

FIG. 2K is apart of a sectional view showing the process of the first embodiment of the semiconductor light-emitting element;

FIG. 2L is apart of a sectional view showing the process of the first embodiment of the semiconductor light-emitting element;

FIG. 2M is apart of a sectional view showing the process of the first embodiment of the semiconductor light-emitting element;

FIG. 3 is a photograph of the semiconductor light-emitting element of the first embodiment, taken from the side of light extraction;

FIG. 4A is a graph showing light intensity distribution of each light-emitting element according to Examples 1 to 3, Reference Example, and Comparative Example;

FIG. 4B is a photograph of the semiconductor light-emitting element, viewed from the direction of light extraction;

FIG. 4C is a graph showing the relationship between the uniformity of emission distribution in the light extraction surface and the thickness of the first protective layer;

FIG. 5 is a sectional view schematically showing a configuration of a second embodiment of the semiconductor light-emitting element;

FIG. 6A is a part of a sectional view showing a process of the second embodiment of the semiconductor light-emitting element;

FIG. 6B is apart of a sectional view showing the process of the second embodiment of the semiconductor light-emitting element;

FIG. 6C is apart of a sectional view showing the process of the second embodiment of the semiconductor light-emitting element;

FIG. 7 is a sectional view schematically showing a configuration of another embodiment of the semiconductor light-emitting element;

FIG. 8 is a sectional view schematically showing a configuration of another embodiment of the semiconductor light-emitting element;

FIG. 9A is a part of a sectional view showing a process of the other embodiment of the semiconductor light-emitting element;

FIG. 9B is apart of a sectional view showing the process of the other embodiment of the semiconductor light-emitting element;

FIG. 9C is apart of a sectional view showing the process of the other embodiment of the semiconductor light-emitting element;

FIG. 10 is a sectional view schematically showing a configuration of a conventional semiconductor light-emitting element; and

FIG. 11 is a photograph of a semiconductor light-emitting element produced by the conventional method, taken from the side of light extraction.

### DETAILED DESCRIPTION OF THE INVENTION

Referring to the drawings, the semiconductor light-emitting element and the production method therefor of the present invention will be described. In each of the following drawings, the dimensional ratio in the drawing and the actual dimensional ratio do not necessarily coincide with each other. In the following, the description “AlGaN” is synonymous with the description AlₘGa₁₋ₘN (0<m<1), and simply describes the composition ratio between Al and Ga for short, and does not intend to limit to the case where the composition ratio between Al and Ga is 1:1. The same also applies to the description “InGaN”.

### First embodiment

A first embodiment of the semiconductor light-emitting element of the present invention will be described.

<Structure>

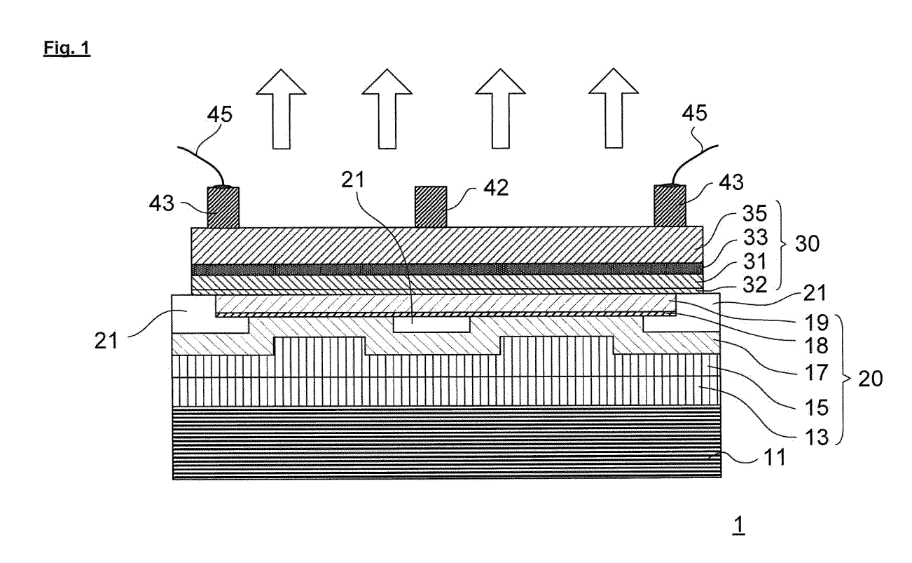

FIG. 1 is a sectional view schematically showing a configuration of a first embodiment of a semiconductor light-emitting element. The semiconductor light-emitting element 1 includes a support substrate 11, a conductive layer 20, an insulating layer 21, a semiconductor layer 30 and n-side electrodes (42, 43). The semiconductor layer 30 is made up of a p-type semiconductor layer 32, a p-type semiconductor layer 31, an active layer 33, and an n-type semiconductor layer 35 laminated sequentially from the side of the support substrate 11.

(Support Substrate 11)

The support substrate 11 is made of a conductive substrate of, for example, CuW, W, or Mo, or a semiconductor substrate of Si or the like.

(Conductive Layer 20)

On the upper layer of the support substrate 11, the conductive layer 20 having a multi-layered structure is formed. The conductive layer 20 includes a reflective electrode 19, a first protective layer 18, a second protective layer 17, a solder layer 15, and a solder layer 13 in the present embodiment.

The solder layer 13 and the solder layer 15 are made of, for example, Au—Sn, Au—In, Au—Cu—Sn, Cu—Sn, Pd—Sn, or Sn. As will be described later, the solder layer 13 and the solder layer 15 are formed by making the solder layer 13 formed on the upper layer of the support substrate 11 and the solder layer 15 formed on the upper layer of another substrate (later-described growth substrate 61) opposite to each other, and then bonding both substrates together.

The reflective electrode 19 is made of Ag in the present embodiment. Ag is a material having high reflectance. In the semiconductor light-emitting element 1, it is assumed that light radiated from the active layer 33 is extracted in the upward direction of FIG. 1 (on the side of the n-type semiconductor layer 35), and the reflective electrode 19 has a function of increasing the luminous efficiency by reflecting light radiated downward from the active layer 33 upwardly. The up-pointing arrow in the FIG. 1 indicates the light extraction direction.

In the configuration of the present embodiment, the reflective electrode 19 is also formed in the position opposite to the n-side electrodes (42, 43) in the direction perpendicular to the plane of the support substrate 11. In particular, as shown in FIG. 1, in the present embodiment, the upper surface of the reflective electrode 19 (the surface opposite to the support substrate 11) is formed so as to be wholly in contact with the p-type semiconductor layer 32. When a voltage is applied between the support substrate 11 and the n-side electrodes (42, 43), a current pathway leading to the n-side electrodes (42, 43) via the support substrate 11, the solder layers (13, 15), the second protective layer 17, the first protective layer 18, the reflective electrode 19, and the semiconductor layer 30 is established.

The first protective layer 18 is formed of an oxide of Ni in the preset embodiment, and has a thickness of equal to or less than 7 nm. The first protective layer 18 is provided for the purpose of preventing voids from being formed on the surface of the reflective electrode 19 as will be described later.

The second protective layer 17 has a multi-layered structure of Ni/Ti/Pt in the present embodiment. In this structure, the Ti/Pt layer is provided for the purpose of preventing the luminous efficiency from decreasing due to deterioration in reflectance as a result of diffusion of the material constituting the solder layer 15 on the side of the reflective electrode 19. The Ni layer is provided for the purpose of preventing the luminous efficiency from decreasing due to deterioration in reflectance as a result of diffusion of the material contained in the Ti/Pt layer, particularly Ti, on the side of the reflective electrode 19.

(Insulating Layer 21)

The insulating layer 21 is made of, for example, SiO₂, SiN, Zr₂O₃, AlN, or Al₂O₃. The insulating layer 21 is formed in the position opposite to the n-side electrodes (42, 43) in the direction perpendicular to the plane of the support substrate 11. The insulating layer 21 is partly in contact with the plane of the side of the support substrate 11 of the first protective layer 18. The insulating layer 21 has a function of extending the current flowing in the active layer 33 in the direction parallel with the plane of the support substrate 11. Further, the insulating layer 21 is also formed in the position outside the semiconductor layer 30, and also functions as an etching stopper layer at the time of separating the element as will be described later in the section of production method. In the semiconductor light-emitting element 1 shown in FIG. 1, the insulating layer 21 in the outer peripheral position is formed to come into contact with the lateral faces of the first protective layer 18 and the reflective electrode 19.

(Semiconductor Layer 30)

As described above, the semiconductor layer 30 is formed by laminating the p-type semiconductor layer 32, the p-type semiconductor layer 31, the active layer 33, and the n-type semiconductor layer 35 sequentially from the side of the support substrate 1.

The p-type semiconductor layer 32 is made of, for example, GaN. The p-type semiconductor layer 31 is made of, for example, AlₘGa₁₋ₘN (0≦m<1). Both of these layers are doped with a p-type impurity such as Mg, Be, Zn, or C. The p-type semiconductor layer 32 includes impurities at higher concentration than the p-type semiconductor layer 31 and functions as a contact layer.

The active layer 33 is formed of, for example, a semiconductor layer in which a light-emitting layer made of InGaN and a barrier layer made of n-type AlGaN are repeatedly laminated in a periodic manner. These layers may be undoped or doped with a p-type or n-type impurity.

The n-type semiconductor layer 35 may have a multi-layered structure including, for example, a layer formed of AlₙGa₁₋ₘN (0≦n<1) and a layer formed of GaN. At least the layer formed of GaN is doped with an n-type impurity such as Si, Ge, S, Se, Sn, or Te.

In the present embodiment, the n-type semiconductor layer 35 corresponds to the “first semiconductor layer”, and the p-type semiconductor layers (31, 32) correspond to the “second semiconductor layer”.

(N-Side Electrode 42, n-Side Electrode 43)

The n-side electrodes (42, 43) are formed on the upper layer of the n-type semiconductor layer 35, and are made of, for example, Cr—Au. The n-side electrode 43 is communicated with a wire 45 made of, for example, Au or Cu, and the other end of the wire 45 is connected with, for example, a feed pattern of the substrate (support substrate 11) on which the semiconductor light-emitting element 1 is arranged (not shown). In brief, the n-side electrode 43 functions as a feed terminal of the semiconductor light-emitting element 1.

On the other hand, the n-side electrode 42 is electrically connected with the n-side electrode 43, and is formed, for example, in the form of network in a broad range on the upper surface of the n-type semiconductor layer 35. That is, the n-side electrode 42 and the n-type semiconductor layer 35 are in contact with each other in a part different from the n-side electrode 43 that forms the feed terminal on the upper surface of the n-type semiconductor layer 35 (the plane opposite to the support substrate 11). This contact allows the current to flow in a broad range of the n-type semiconductor layer 35 with regard to the direction parallel with the plane of the support substrate 11 during supplying electricity, so that the current is allowed to flow in a broad range in the active layer 33.

Although not shown in the drawing, an insulating layer may be formed as a protective film on the lateral face of the semiconductor layer 30. The insulating layer as a protective film is preferably made of a material having translucency (for example, SiO₂). In the above-described embodiment, while one material constituting the p-type semiconductor layer 31 is described as AlₘGa₁₋ₘN (0≦m<1) and one material constituting the n-type semiconductor layer 35 is described as AlₙGa₁₋ₘN (0≦n<1), they may be the same materials.

Also, fine irregularities (mesa structure) may be formed on the upper surface of the n-type semiconductor layer 35 for the purpose of further increasing the light extraction efficiency.

According to the semiconductor light-emitting element 1, the fact that emission intensity increases and light extraction efficiency increases as compared with a conventional semiconductor light-emitting element will be described with reference to Examples after description of the production method.

<Production Method>

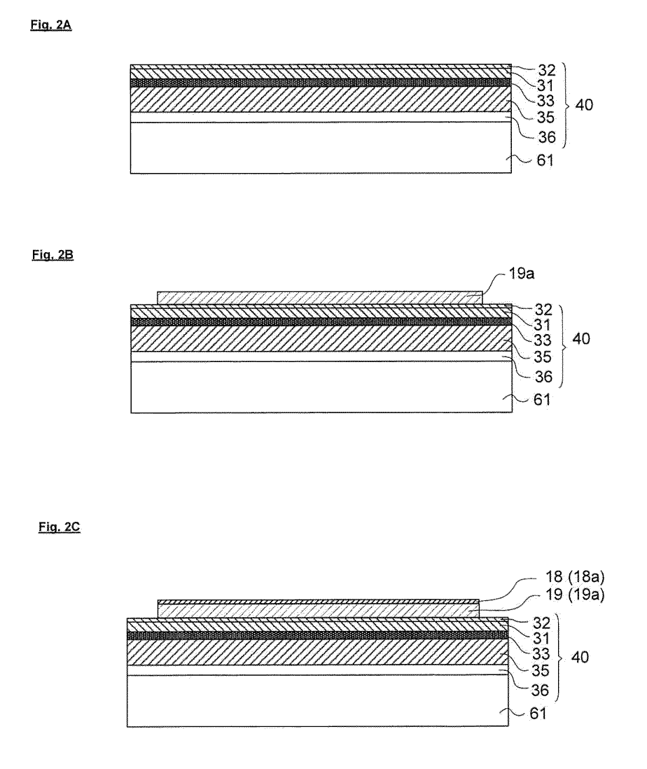

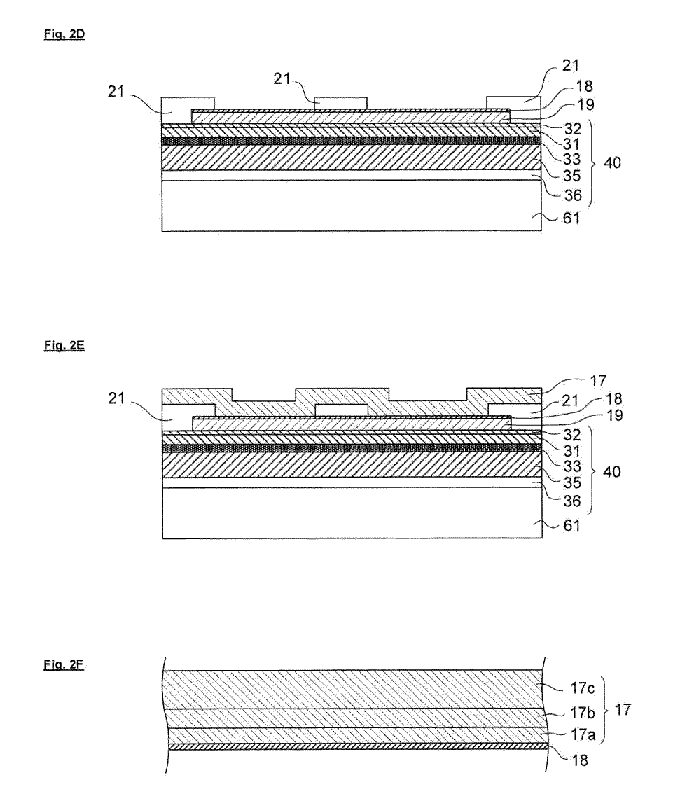

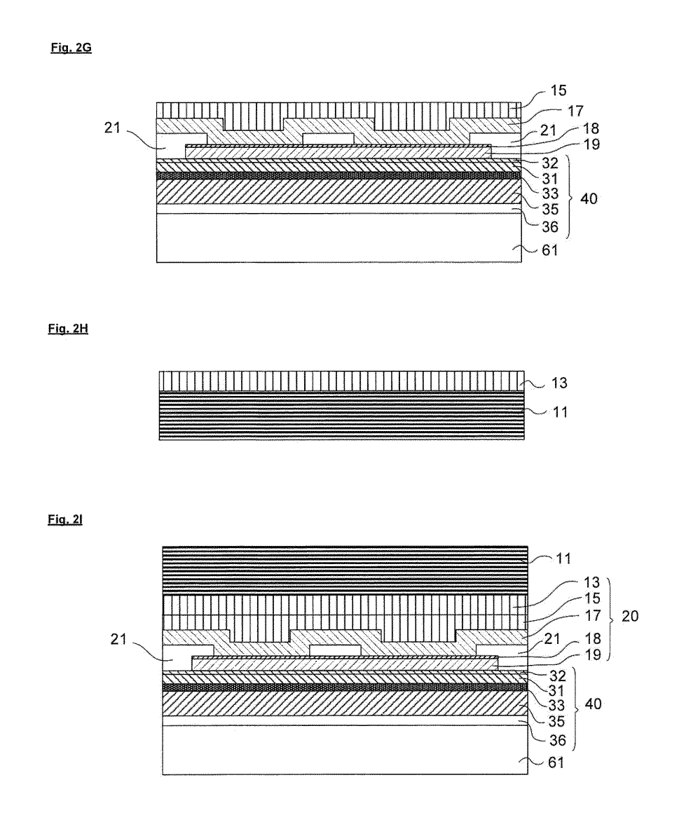

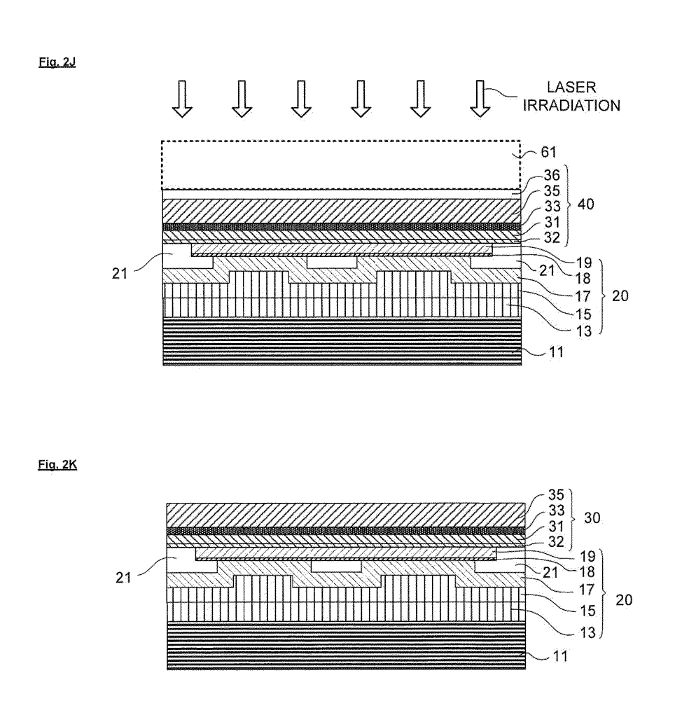

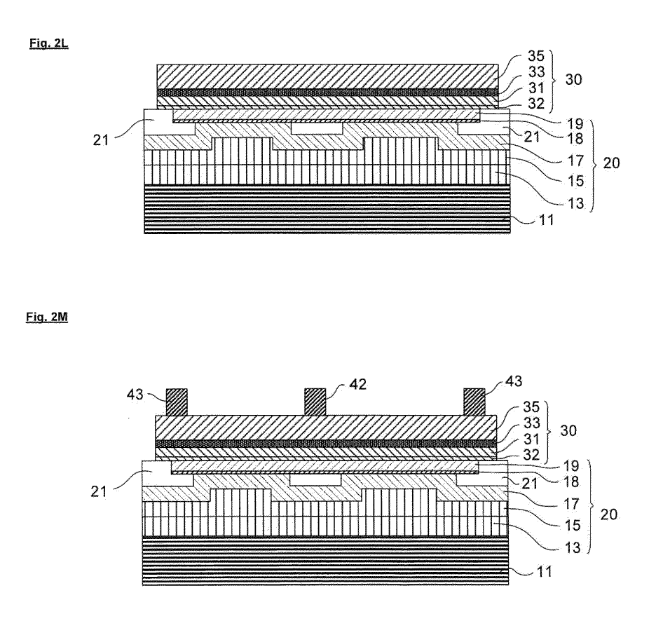

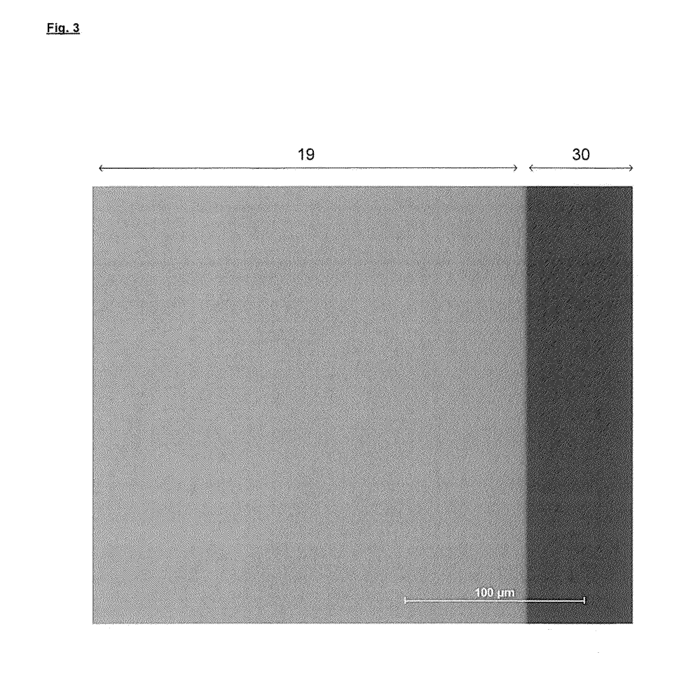

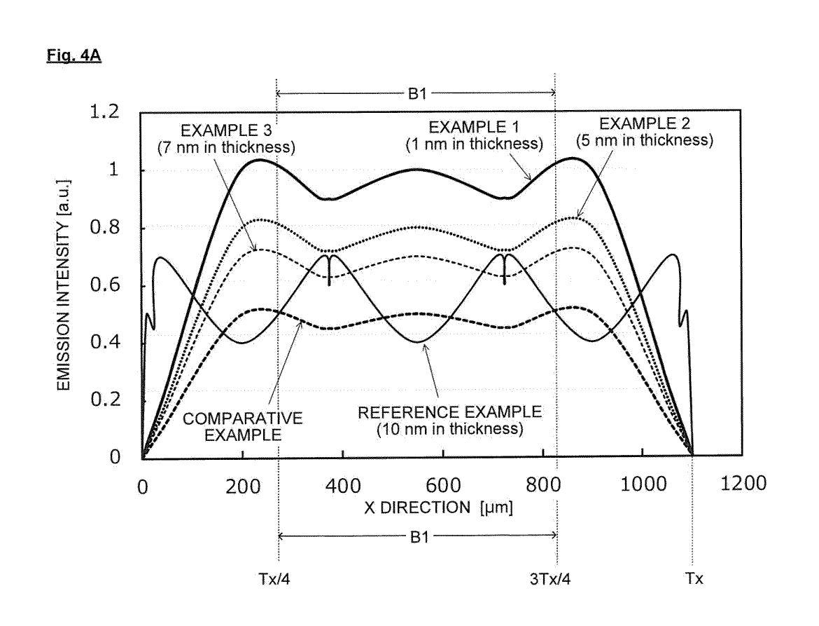

Next, one example of a method for producing the semiconductor light-emitting element 1 will be described with reference to the sectional views of a process shown in FIG. 2A to FIG. 2M. The production conditions and dimensions such as thickness described hereinafter are given merely for exemplification, and the present invention will not be limited by these numerical values.

(Step S1)

A growth substrate 61 is prepared (see FIG. 2A). As the growth substrate 61, for example, a c-plane sapphire substrate can be used.

As a preparative step, the growth substrate 61 is subjected to cleaning. The cleaning is conducted, as a more concrete example, by placing the growth substrate 61 in the treatment furnace of a MOCVD (Metal Organic Chemical Vapor Deposition) device, and elevating the temperature in the furnace to, for example, 1150° C. under the flow of hydrogen gas at a flow rate of 10 slm in the treatment furnace.

Step S1 corresponds to step (a).

(Step S2)

On the upper surface of the growth substrate 61, an epitaxial layer 40 having an undoped layer 36, the n-type semiconductor layer 35, the active layer 33, the p-type semiconductor layer 31, and the p-type semiconductor layer 32 is formed. One example of the procedure is as follows.

<Formation of Undoped Layer 36>

On the upper surface of the growth substrate 61 (c-plane sapphire substrate), a low-temperature buffer layer comprising GaN is formed, and further a foundation layer formed comprising GaN is formed thereon. These low-temperature buffer layer and foundation layer correspond to the undoped layer 36.

A concrete method for forming the undoped layer 36 is, for example, as follows. First, the pressure and the temperature in the furnace of the MOCVD device are set at 100 kPa and 480° C., respectively. Then trimethylgallium (TMG) at a flow rate of 50 μmol/minute and ammonia at a flow rate of 250000 vol/minute are supplied as a source gas into the treatment furnace for 68 seconds under the flow of nitrogen gas and hydrogen gas each at a flow rate of 5 slm as a carrier gas in the treatment furnace. As a result, a low-temperature buffer layer comprising GaN having a thickness of 20 nm is formed on the surface of the growth substrate 61.

Next, the temperature in the furnace of the MOCVD device is elevated to 1150° C. Then, TMG at a flow rate of 100 μmol/minute and ammonia at a flow rate of 250000 vol/minute are supplied as a source gas into the treatment furnace for 30 minutes under the flow of nitrogen gas at a flow rate of 20 slm and hydrogen gas at a flow rate of 15 slm as a carrier gas in the treatment furnace. As a result, a foundation layer comprising GaN having a thickness of 1.7 μm is formed on the surface of the low-temperature buffer layer.

<Formation of n-Type Semiconductor Layer 35>

Next, on the upper surface of the undoped layer 36, the n-type semiconductor layer 35 having a composition of, for example, AlₙGa₁₋ₘN (0≦n<1) is formed.

A more concrete method for forming the n-type semiconductor layer 35 is, for example, as follows. The pressure in the furnace of the MOCVD device is set at 30 kPa while the temperature in the furnace is kept at 1150° C. Then TMG at a flow rate of 94 vol/minute, trimethylaluminum (TMA) at a flow rate of 6 vol/minute, ammonia at a flow rate of 250000 vol/minute and tetraethylsilane at a flow rate of 0.025 μmol/minute are supplied as a source gas into the treatment furnace for 60 minutes under the flow of nitrogen gas at a flow rate of 20 slm and hydrogen gas at a flow late of 15 slm as a carrier gas in the treatment furnace. As a result, the n-type semiconductor layer 35 having a composition of, for example, Al_{0.06}Ga_{0.94}N, a Si concentration of 3×10¹⁹/cm³ and a thickness of 2 μm is formed on the undoped layer 36.

Thereafter, an n-type GaN having a thickness of 5 nm may be formed on the n-type AlGaN layer by stopping supply of TMA and supplying the remainder of the source gas for 6 seconds. In this case, these n-type AlGaN layer and n-type GaN layer correspond to the n-type semiconductor layer 35.

In the above description, although the case of using Si as the n-type impurity contained in the n-type semiconductor layer 35 is described, Ge, S, Se, Sn or Te can be used besides Si as the n-type impurity.

As described above, the n-type semiconductor layer 35 corresponds to “first semiconductor layer”.

<Formation of Active Layer 33>

Next, on the upper surface of the n-type semiconductor layer 35, the active layer 33 is formed in which a light-emitting layer made of InGaN and a barrier layer made of n-type AlGaN are repeatedly laminated in a periodic manner.

A more concrete method for forming the active layer 33 is, for example, as follows. The pressure and the temperature in the furnace of the MOCVD device are set at 100 kPa and 830° C., respectively. Then the step of supplying TMG at a flow rate of 10 vol/minute, trimethylindium (TMI) at a flow rate of 12 vol/minute and ammonia at a flow rate of 300000 mmol/minute as a source gas into the treatment furnace for 48 seconds under the flow of nitrogen gas at a flow rate of 15 slm and hydrogen gas at a flow rate of 1 slm as a carrier gas in the treatment furnace is conducted. Then the step of supplying TMG at a flow rate of 10 mmol/minute, TMA at a flow rate of 1.6 vol/minute, tetraethylsilane at a flow rate of 0.002 mmol/minute and ammonia at a flow rate of 300000 mmol/minute into the treatment furnace for 120 seconds is conducted. By repeating these two steps, the active layer 33 made up of a light-emitting layer composed of InGaN having a thickness of 2 nm and a barrier layer composed of n-type AlGaN having a thickness of 7 nm in 15 periods is formed on the upper surface of the n-type nitride semiconductor layer 35.

<Formation of p-Type Semiconductor Layer 31>

Next, on the active layer 33, the p-type semiconductor layer 31 formed of, for example, AlₘGa₁₋ₘN (0≦m≦1) is formed.

Amore concrete method for forming the p-type semiconductor layer 31 is, for example, as follows. The pressure in the furnace of the MOCVD device is kept at 100 kPa, and the temperature in the furnace is elevated to 1025° C. under the flow of nitrogen gas at a flow rate of 15 slm and hydrogen gas at a flow rate of 25 slm as a carrier gas in the treatment furnace. Then TMG at a flow rate of 35 mmol/minute, TMA at a flow rate of 20 vol/minute, ammonia at a flow rate of 250000 mmol/minute and bis(cyclopentadienyl)magnesium (Cp₂Mg) at a flow rate of 0.1 vol/minute for doping with a p-type impurity are supplied as a source gas into the treatment furnace for 60 seconds. As a result, on the upper surface of the active layer 33, a hole supply layer having a thickness of 20 nm and a composition of Al_{0.3}Ga_{0.7}N is formed. Then the flow rate of TMA is changed to 4 μmol/minute and the source gas is supplied for 360 seconds, so that a hole supply layer having a thickness of 120 nm and a composition of Al_{0.13}Ga_{0.87}N is formed. These hole supply layers form the p-type semiconductor layer 31. The p-type semiconductor layer 31 has p-type impurity concentration of, for example, about 3×10¹⁹/cm³.

<Formation of p-Type Semiconductor Layer 32>

Thereafter, supply of TMA is stopped, the flow rate of Cp₂Mg is changed to 0.2 mmol/minute, and the source gas is supplied for 20 seconds to form the p-type semiconductor layer 32 having a thickness of, for example, about 5 nm and comprising p-type GaN having a p-type impurity concentration of about 1×10²⁰/cm³.

As described above, the p-type semiconductor layer 31 and the p-type semiconductor layer 32 correspond to the “second semiconductor layer”.

Step S2 corresponds to step (b).

(Step S3)

The wafer formed in step S2 is subjected to an activation treatment. As one concrete example, an activation treatment is conducted at 650° C. for 15 minutes under a nitrogen atmosphere by using a RTA (Rapid Thermal Anneal) device.

(Step S4)

Next, as shown in FIG. 2B, an electrode material (first conductive layer 19a) constituting the reflective electrode 19 is vapor deposited in a predetermined part on the upper surface of the p-type semiconductor layer 32. FIG. 2B shows a configuration such that the reflective electrode 19 is formed on almost the whole surface of the p-type semiconductor layer 32 inside the area where the p-type semiconductor layer 32 is formed. More concretely, by depositing Ni having a thickness of 0.7 nm and Ag having a thickness of 130 nm on the upper surface of the p-type semiconductor layer 32 by means of, for example, a sputtering device, the first conductive layer 19a is vapor deposited. The thickness of the first conductive layer 19a is preferably equal to or more than 50 nm and equal to or less than 150 nm.

While an alloy of Ni and Ag is employed as the material for the first conductive layer 19a in this context, a material containing Al or Rh can also be used.

Step S4 corresponds to step (c).

(Step S5)

After vapor deposition of the first conductive layer 19a in step S4, a conductive material (second conductive layer 18a) constituting the first protective layer 18 is sequentially vapor deposited on the whole upper surface of the first conductive layer 19a as shown in FIG. 2C without previously conducting annealing. In the present embodiment, the second conductive layer 18a is composed of a Ni layer having a thickness of equal to or less than 7 nm (for example, thickness of about 2 nm).

Step S5 corresponds to step (d).

(Step S6)

An annealing treatment using an RTA device or the like is conducted at 350° C. to 550° C. in a dry air atmosphere for 60 seconds to 300 seconds to form ohmic contact between the first conductive layer 19a and the p-type semiconductor layers (31, 32). Through this step, the first conductive layer 19a functions as the reflective electrode 19 (see FIG. 2C).

By conducting the annealing step of step S6 in the state that the second conductive layer 18a is formed on the whole upper surface of the first conductive layer 19a in step S5, the second conductive layer 18a functions as a barrier layer, and the effect of preventing formation of voids in the upper surface of the reflective electrode 19 is achieved. At the time of this annealing, the second conductive layer 18a is oxidized to turn into the first protective layer 18 made of a conductive oxide. In the present embodiment, the first protective layer 18 is made of a Ni oxide such as NiO (see FIG. 2C).

Step S6 corresponds to step (e).

(Step S7)

Next, as shown in FIG. 2D, the insulating layer 21 is formed in a predetermined part on the upper surface of the first protective layer 18 and on the exposed upper surface of the p-type semiconductor layer 32. It is preferred to form the insulating layer 21 particularly in the region including the position opposite to the region where the n-side electrodes (42, 43) are to be formed in the subsequent step in the direction perpendicular to the substrate plane. At this time, as shown in FIG. 2D, the insulating layer 21 can be formed so that a part thereof covers the lateral faces of the first protective layer 18 and the reflective electrode 19.

More concretely, for example, SiO₂ is deposited into a thickness of about 200 nm by sputtering while the upper surface of the first protective layer 18 concerning the region where the insulating layer 21 is not formed is masked. The material to be deposited should be an insulating material, and for example, SiN, Al₂O₂ or the like may be used.

(Step S8)

As shown in FIG. 2E, the second protective layer 17 having conductivity is formed so as to cover the upper surfaces of the first protective layer 18 and the insulating layer 21. In the present embodiment, as shown in the enlarged view of FIG. 2F, the second protective layer 17 has a multi-layered structure laminating a Ni layer 17a having a thickness of about 80 nm, a Ti layer 17b having a thickness of about 100 nm, and a Pt layer 17c having a thickness of about 200 nm. These conductive layers can be vapor deposited by using, for example, an electron-beam deposition device (EB device).

The Ni layer 17a can include a layer containing Ni as a main material. The Ti layer 17b can include a layer containing Ti as a main material. The Pt layer 17c can include a layer containing Pt as a main material. The Ti layer 17b and the Pt layer 17c may be repeatedly formed in a plurality of periods.

The Ti layer 17b and the Pt layer 17c are provided for preventing the material constituting the solder layer 15 formed in next step S9 from diffusing on the side of the reflective electrode 19 to deteriorate the reflectance of the reflective electrode 19. The Ni layer 17a is provided for preventing Ti of the Ti layer 17b from diffusing on the side of the reflective electrode 19 to deteriorate the reflectance of the reflective electrode 19.

In the present embodiment, the second conductive layer 18a formed in step S5 includes a Ni layer. However, there can be the case where the function of preventing Ti constituting the Ti layer 17b from diffusing into the reflective electrode 19 cannot be sufficiently exerted, because the second conductive layer 18a includes a very thin film having a thickness of equal to or less than 7 nm as described above. For avoiding such a situation, the second protective layer 17 includes a conductive multi-layered film containing the Ni layer 17a.

Step S8 corresponds to step (f).

(Step S9)

As shown in FIG. 2G, the solder layer 15 is formed on the upper surface of the second protective layer 17. In one concrete example, Ti having a thickness of 10 nm is vapor deposited on the upper surface of the Pt layer 17c constituting the uppermost layer of the second protective layer 17, and then an Au—Sn solder composed of Au 80% and Sn 20% is vapor deposited in a thickness of 3 w, and thus the solder layer 15 is formed.

In this step of forming the solder layer 15, the solder layer 13 may also be formed on the upper surface of the support substrate 11 prepared separately from the growth substrate 61 (see FIG. 2H). This solder layer 13 may be made of the same material as the solder layer 15, and the growth substrate 61 and the support substrate 11 are bonded together by being joined with the solder layer 13 in the subsequent step. As the support substrate 11, for example, CuW is used as already described in the section of the structure.

Further, as shown in FIG. 2H, for preventing diffusion of the material of the solder layer 13, a protective layer including a Ti/Pt layer may be formed on the support substrate 11, and the solder layer 13 may be formed on the protective layer.

(Step S10)

Next, as shown in FIG. 2I, the growth substrate 61 and the support substrate 11 are bonded together. As one example, the solder layer 15 and the solder layer 13 formed on the support substrate 11 are bonded together at a temperature of 280° C. under a pressure of 0.2 MPa.

(Step S11)

Next, as shown in FIG. 2J, the growth substrate 61 is exfoliated. More concretely, in the state that the growth substrate 61 faces up and the support substrate 11 faces down, KrF excimer laser is irradiated from the side of the growth substrate 61 to disintegrate the interface between the growth substrate 61 and the epitaxial layer 40, so that the growth substrate 61 is exfoliated. While sapphire that forms the growth substrate 61 transmits the laser, GaN (undoped layer 36) beneath the growth substrate 61 absorbs the laser. According, the temperature of the interface increases and GaN is disintegrated. As a result, the growth substrate 61 is exfoliated.

Thereafter, GaN (undoped layer 36) remaining on the wafer is removed by wet etching using hydrochloric acid or the like or by dry etching using an ICP device, to expose the n-type semiconductor layer 35 (see FIG. 2K). In step S11, the undoped layer 36 is removed, and the semiconductor layer 30 made up of the p-type semiconductor layer 32, the p-type semiconductor layer 31, the active layer 33, and the n-type semiconductor layer 35 that are laminated in this order from the side of the support substrate 11 remains.

(Step S12)

Next, the adjacent elements are separated from each other as shown in FIG. 2L. Concretely, for the boundary region between adjacent elements, the semiconductor layer 30 is etched by using an ICP device until the upper surface of the insulating layer 21 is exposed. At this time, the insulating layer 21 also functions as an etching stopper as described above.

(Step S13)

Then as shown in FIG. 2M, in the positions vertically above the part where the insulating layer 21 is formed on the upper surface of the n-type semiconductor layer 35, the n-side electrodes (42, 43) are formed. Concretely, after forming electrodes composed of Cr having a thickness of 100 nm and Au having a thickness of 3 μm, sintering is conducted in a nitrogen atmosphere at 250° C. for 1 minute.

Then the elements are separated from each other, for example, by using a laser dicing device, and the back face of the support substrate 11 is joined with a package, for example, with an Ag paste, and wire bonding is conducted for the n-side electrode 43 serving as a feed terminal. The wire bonding is conducted, for example, by connecting the wire 45 comprising Au to the bonding region of 0100 μm under a load of 50 g. As a result, the semiconductor light-emitting element 1 as shown in FIG. 1 is formed.

From the viewpoint of further increasing the light extraction efficiency, irregularities (mesa structure) may be formed on the surface of the n-type semiconductor layer 35 by dipping in an alkaline solution such as KOH between step S12 and step S13. After forming the n-side electrodes (42, 43) on the upper surface of the n-type semiconductor layer 35, an insulating layer may be formed so as to cover the lateral face of the semiconductor layer 30.

### Examples

Hereinafter, the fact that light output is improved by the semiconductor light-emitting element 1 as compared with a conventional semiconductor light-emitting element will be described with reference to Examples.

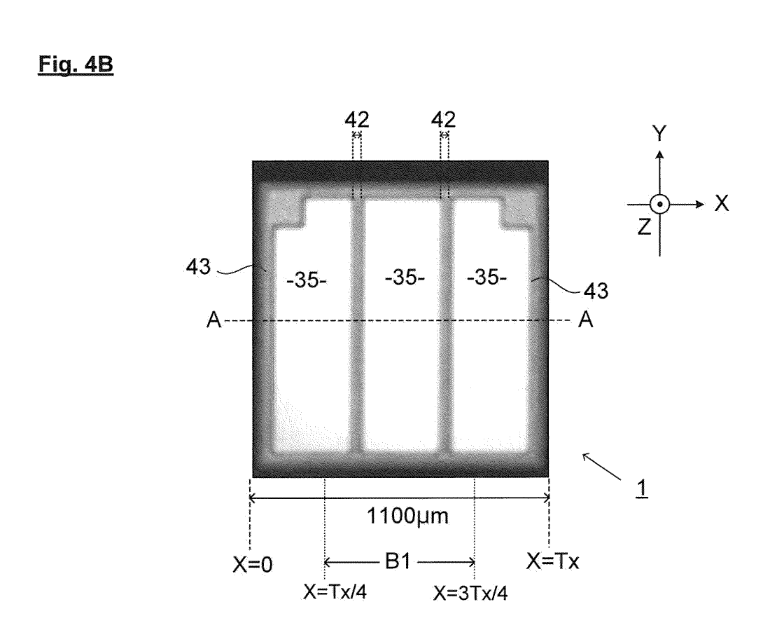

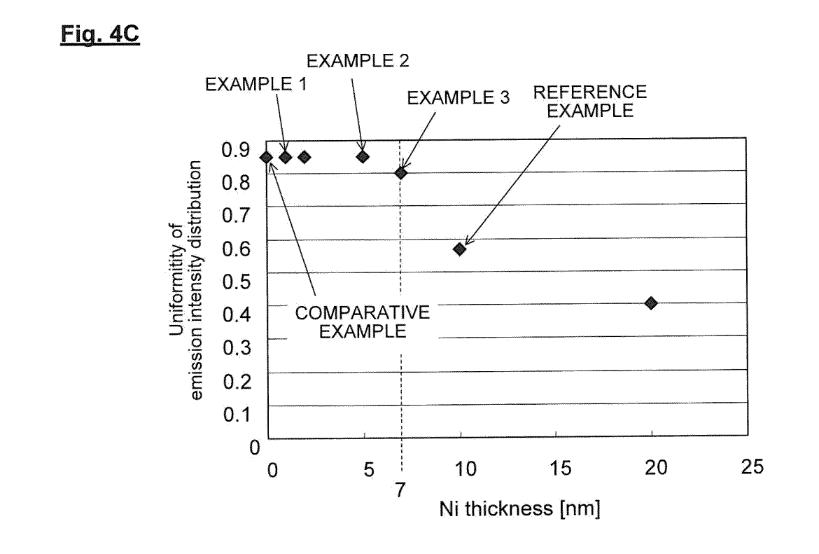

FIG. 3 is a photograph taken through the growth substrate 61 from the side of the growth substrate 61 shown in FIG. 2C in the same manner as FIG. 11 after conduction of steps S1 to S6 as described above. In contrast to the photograph of FIG. 2, no black dot appears on the surface of the reflective electrode 19, revealing that no void is formed. This increases light extraction efficiency as compared with a conventional semiconductor light-emitting element 90. This point will be further described later with reference to FIG. 4A.

### Examples 1 to 3, Reference Example

Semiconductor light-emitting elements produced through steps S1 to S13 described above were given as Examples 1 to 3 and Reference Example.

In Example 1, the second conductive layer 18a formed of Ni having a thickness of 1 nm was vapor deposited in step S5 to form a semiconductor light-emitting element.

In Example 2, the second conductive layer 18a formed of Ni having a thickness of 5 nm was vapor deposited in step S5 to form a semiconductor light-emitting element.

In Example 3, the second conductive layer 18a formed of Ni having a thickness of 7 nm was vapor deposited in step S5 to form a semiconductor light-emitting element.

In Reference Example, the second conductive layer 18a formed of Ni having a thickness of 10 nm was vapor deposited in step S5 to form a semiconductor light-emitting element.

### Comparative Example

A semiconductor light-emitting element produced through steps S1 to S4 and steps S6 to S13 described above was given as Comparative Example. In other words, the semiconductor light-emitting element of Comparative Example is produced without formation of the second conductive layer 18a, and does not have the first protective layer 18. This light-emitting element of Comparative Example assumes a conventional light-emitting element.

FIG. 4A is a graph showing distribution of emission intensity of each light-emitting element according to Examples 1 to 3, Reference Example, and Comparative Example. FIG. 4B is a photograph of the semiconductor light-emitting element, viewed from the direction of light extraction.

As shown in FIG. 4B, two directions parallel with the plane of the support substrate 11 are defined as an X direction and a Y direction, and of these directions, the direction in which the n-side electrodes (42, 43) are spaced is assigned to the X direction. When the direction perpendicular to the plane of the support substrate 11 is defined as a Z direction, FIG. 1 corresponds to a sectional view when the semiconductor light-emitting element 1 is cut along the plane parallel with the XZ plane. The photograph of FIG. 4B corresponds to the semiconductor light-emitting element 1 in which the two n-side electrodes 42 are formed by being extended along the X direction.

Regarding the light intensity received on the side of the light extraction surface, FIG. 4A is a graph plotting the light intensity on an A-A line which is parallel with the X direction and passes through the center position of the Y coordinate of the semiconductor light-emitting element 1 according to X coordinates. The light intensity was measured by using a beam profiler.

FIG. 4A reveals that the light intensity increases in almost all of the X coordinates in any of Example 1, Example 2 and Example 3 having a thickness of the first protective layer 18 of 1 nm, 5 nm, and 7 nm, respectively, as compared with Comparative Example.

In Reference Example having a thickness of the first protective layer 18 of 10 nm, the light intensity increases as compared with Comparative Example in a certain part of X-coordinate positions, however, the light intensity deteriorates as compared with Comparative Example in a part of other positions. Analysis of the part where the light intensity increases in the light-emitting element of Reference Example as compared with Comparative Example revealed that the part corresponds to a part in the vicinity of the n-side electrodes (42, 43) in the light extraction surface.

As described with reference to FIG. 3 and FIG. 11, by providing the first protective layer 18, it is possible to prevent formation of voids in the surface of the reflective electrode 19. In brief, it is conceivable that by producing the semiconductor light-emitting element 1 having the first protective layer 18, deterioration in reflectance caused by the voids is alleviated, and the emission intensity increases.

However, according to diligent efforts of the inventor, it was confirmed that when various different semiconductor light-emitting elements 1 having different thicknesses of the first protective layer 18 are produced, distribution of emission intensity arises when the thickness is larger than a certain thickness as shown in FIG. 4A. In particular, when the thickness of the first protective layer 18 is 10 nm as shown in Reference Example, the total quantity of light increases as compared with a conventional semiconductor light-emitting element, however, decrease in emission intensity as compared with a conventional element is observed depending on the position.

If the large distribution of emission intensity arises as in Reference Example, it is assumed that unevenness arises when light generated by the light-emitting element is used as alight source. Therefore, it is preferred that the distribution of emission intensity depending on the position is as small as possible.

FIG. 4C shows the ratio of the minimum light intensity to the maximum light intensity (hereinafter referred to as “emission distribution uniformity”) for the region in which X coordinate represents near a predetermined center in the light extraction surface (hereinafter referred to as “objective region B1”) calculated from the graph of FIG. 4A. Here, the objective region B1 is defined so that the X coordinate ranges from Tx/4 to 3Tx/4 when the light extraction surface occupies the positions from 0 to Tx in the X coordinate (see FIG. 4A, FIG. 4B). In FIG. 4C, the vertical axis represents the emission distribution uniformity and the horizontal axis represents the thickness of the first protective layer 18.

According to FIG. 4C, high emission distribution uniformity comparative to that of Comparative Example not having the first protective layer 18 is observed within the range up to 7 nm of thickness of the first protective layer 18, however, remarkable reduction in the emission distribution uniformity is observed when the thickness of the first protective layer 18 is 10 nm as compared with the case where the thickness is 7 nm. Although not shown in FIG. 4A, when a light-emitting element produced to include the first protective layer 18 having a thickness of 20 nm was measured in a similar manner, greater deterioration in emission distribution uniformity as compared with the light-emitting element produced to include the first protective layer 18 having a thickness of 10 nm was observed (see FIG. 4C).

Accordingly, it is confirmed that emission intensity is increased as compared with a conventional element when the semiconductor light-emitting element is produced by vapor depositing a conductive material (first conductive layer 19a) constituting the reflective electrode 19, and then vapor depositing a conductive material (second conductive layer 18a) constituting the first protective layer 18 on the upper surface of the first conductive layer 19a without previously conducting an annealing treatment, and then conducting an annealing treatment.

However, when the thickness of the first protective layer 18 (second conductive layer 18a) was set to at least equal to or longer than 10 nm, remarkable deterioration in emission distribution uniformity was observed as compared with a conventional semiconductor light-emitting element.

Therefore, by producing a semiconductor light-emitting element by vapor depositing the conductive material (second conductive layer 18a) constituting the first protective layer 18 to have a thickness as small as less than 10 nm, preferably equal to or less than 7 nm without previously conducting an annealing treatment after vapor deposition of the first conductive layer 19a, and then conducting an annealing treatment, it is possible to realize a semiconductor light-emitting element having emission distribution uniformity comparative to that of a conventional element and increased emission intensity as compared with a conventional element. According to FIG. 4A, since the emission intensity is increased as the thickness of the first protective layer 18 decreases, it is conceivable that the thickness as small as equal to or less than 7 nm is more preferable.

According to the configuration shown in FIG. 1, while the reflective electrode 19 is formed in the position opposite to the n-side electrodes (42, 43) at the direction perpendicular to the plane of the support substrate 11 (hereinafter, referred to as “first direction”), the reflective electrode 19 is in contact with the insulating layer 21 in the plane on the side of the support substrate 11 of the reflective electrode 19 at that position. Therefore, at the position opposite to the n-side electrodes (42, 43) in the first direction, the current will not flow along the first direction between the reflective electrode 19 and the second protective layer 17.

Since the current pathway is formed in the region where the insulating layer 21 is not formed, a large part of current will not flow only in the active layer 33 in the region sandwiched between the reflective electrode 19 and the n-side electrodes (42, 43) even if the reflective electrode 19 and the n-side electrodes (42, 43) have an opposite positional relationship in the first direction according to the above configuration. That is, according to the semiconductor light-emitting element 1 shown in FIG. 1, the effect of extending the current flowing in the active layer 33 in the direction parallel with the substrate plane of the support substrate 11 (horizontal direction) is achieved without providing an insulating layer on the upper layer of the reflective electrode 19.

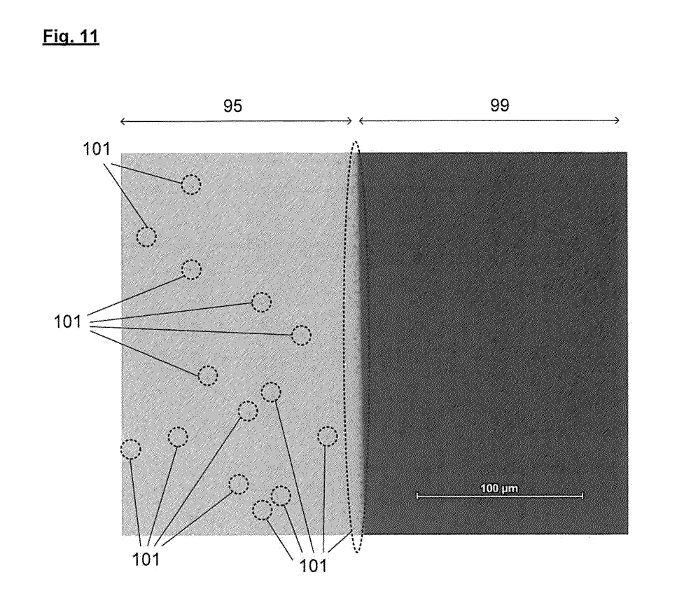

Also in the semiconductor light-emitting element 90 shown in FIG. 10, the insulating layer 94 is provided for the purpose of extending the current in the direction parallel with the plane of the support substrate 91. However, light radiated toward the support substrate 91 from the active layer 97 will pass through the insulating layer 94 twice, before and after the light is reflected by the reflective film 93, while the light is reflected by the reflective film 93 and extracted upwardly.

Patent Document 1 recites SiO₂, Al₂O₂, ZrO₂, TiO₂ and the like materials as a material for the insulating layer 94. When the insulating layer 94 is made of such a material, several % of light passing through the insulating layer 94 is absorbed by the insulating film 94 although the insulating layer 94 is formed as a transparent film. More specifically, before light from the active layer 97 passes through the insulating layer 94 and reaches the reflective film 93, about 3 to 4% of the light is absorbed, and further before light reflected by the reflective film 93 passes through the insulating layer 94 and is then extracted outside on the side of the n-type semiconductor layer 98, about 3 to 4% of the light is absorbed.

In contrast to this, according to the configuration shown in FIG. 1, light radiated from the active layer 33 toward the support substrate 11 will not be absorbed by the insulating layer before the light is reflected by the reflective electrode 19 and extracted on the side of the n-type semiconductor layer 35. The aforementioned light-emitting element of Comparative Example has the same configuration as FIG. 1 except that the first protective layer 18 is not provided. That is, it is conceivable that the semiconductor light-emitting element of Patent Document 1 exhibits still lower emission intensity than the semiconductor light-emitting element of Comparative Example as shown in FIG. 4A or FIG. 4C. Conversely, according to the semiconductor light-emitting element 1 of the present invention, the light extraction efficiency is greatly improved in comparison with the semiconductor light-emitting element of Patent Document 1.

### Second Embodiment

A second embodiment of the semiconductor light-emitting element of the present invention will be described. The constituent identical to that of the first embodiment is denoted by the same reference numeral, and the description thereof will be omitted.

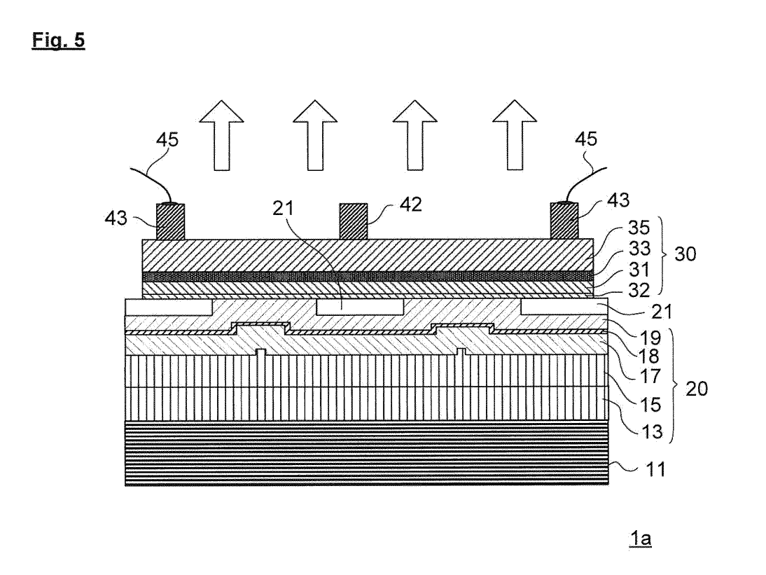

FIG. 5 is a sectional view schematically showing a configuration of a second embodiment of the semiconductor light-emitting element. The semiconductor light-emitting element 1a differs from the semiconductor light-emitting element 1 of the first embodiment in that the insulating layer 21 is formed in contact with the p-type semiconductor layer 32. More specifically, the semiconductor light-emitting element 1a differs in that the insulating layer 21 is formed prior to the reflective electrode 19 (first conductive layer 19a) and the first protective layer 18 (second conductive layer 18a) in production.

In the following description of a method for producing the semiconductor light-emitting element 1a shown in FIG. 5, only the part different from that in the first embodiment will be described.

After forming the epitaxial layer 40 on the upper surface of the growth substrate 61 by conducting steps S1 to S3 in the same manner as in the first embodiment, an activation treatment is conducted (see FIG. 2A).

(Step S3A)

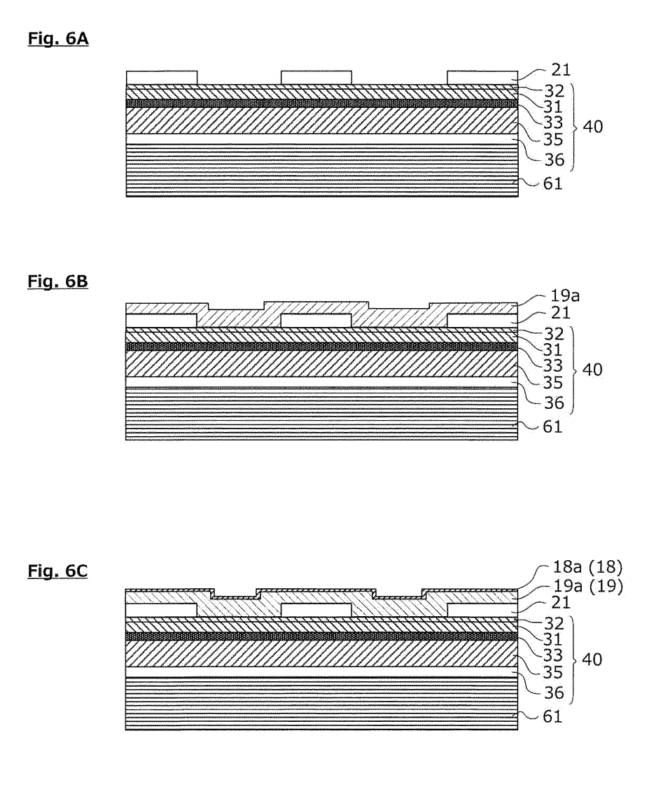

Next, as shown in FIG. 6A, the insulating layer 21 is formed in the part including the position opposite to the region where the n-side electrodes (42, 43) are to be formed in a later step in the direction perpendicular to the plane of the support substrate 11 (first direction) in the same manner as in step S7 of the first embodiment.

(Step S3B)

Next, as shown in FIG. 6B, an electrode material (first conductive layer 19a) constituting the reflective electrode 19 is vapor deposited in the same manner as in step S4. In the present embodiment, the first conductive layer 19a is vapor deposited on the whole surface so as to cover the upper surfaces of the insulating layer 21 and the p-type semiconductor layer 32.

(Step S3C)

Next, as shown in FIG. 6C, a conductive material (second conductive layer 18a) constituting the first protective layer 18 is vapor deposited as a thin film having a thickness of equal to or less than 7 nm on the whole upper surface of the first conductive layer 19a in the same manner as in step S5. Also at this time, this step is conducted without previously conducting an annealing step after conduction of step S3B as is the case with the first embodiment.

Then, an annealing treatment is carried out in the same manner as in step S6 to form ohmic contact between the first conductive layer 19a and the p-type semiconductor layers (31, 32). Through this step, the first conductive layer 19a functions as the reflective electrode 19, and the second conductive layer 18a turns into a conductive oxide layer (first protective layer 18).

Subsequently, steps S7 to S13 are conducted in the same manner as in the first embodiment to form the semiconductor light-emitting element 1a shown in FIG. 5.

Also in the configuration of the present embodiment, since an annealing step is not conducted after vapor deposition of the first conductive layer 19a constituting the reflective electrode 19, and an annealing step is conducted in the state that the whole upper surface of the first conductive layer 19a is covered with the second conductive layer 18a (first protective layer 18) as is the case with the first embodiment, formation of voids between the reflective electrode 19 and the semiconductor layer 30 is suppressed.

Further, since the annealing is conducted after vapor deposition of the second conductive layer 18a as a thin film having a thickness of equal to or less than 7 nm as is the case with the first embodiment, formation of voids between the second conductive layer 18a and the first conductive layer 19a is also prevented.

According to the semiconductor light-emitting element 1a shown in FIG. 5, light radiated downward from the active layer 33 will pass through the insulating layer 21 twice, before and after the light is reflected by the reflective electrode 19, while the light is reflected by the reflective electrode 19 and extracted upwardly. Therefore, the light extraction efficiency is deteriorated more or less as compared with the configuration of the first embodiment in the point that the light is partially absorbed in the insulating layer 21. However, since formation of voids in the upper surface of the reflective electrode 19 is prevented and high reflectance is realized, the light extraction efficiency is increased in comparison with a conventional case.

### Other Embodiments

In the following, other embodiments will be described.

<1> The present invention is not limited to the structures shown FIG. 1 and FIG. 5 as described above. That is, the present invention is directed to a semiconductor light-emitting element realized by vapor depositing the conductive material (first conductive layer 19a) constituting the reflective electrode 19, and then vapor depositing the conductive material (second conductive layer 18a) constituting the first protective layer 18 as a thin film on the upper surface of the first conductive layer 19a without previously conducting an annealing treatment, and then conducting an annealing treatment.

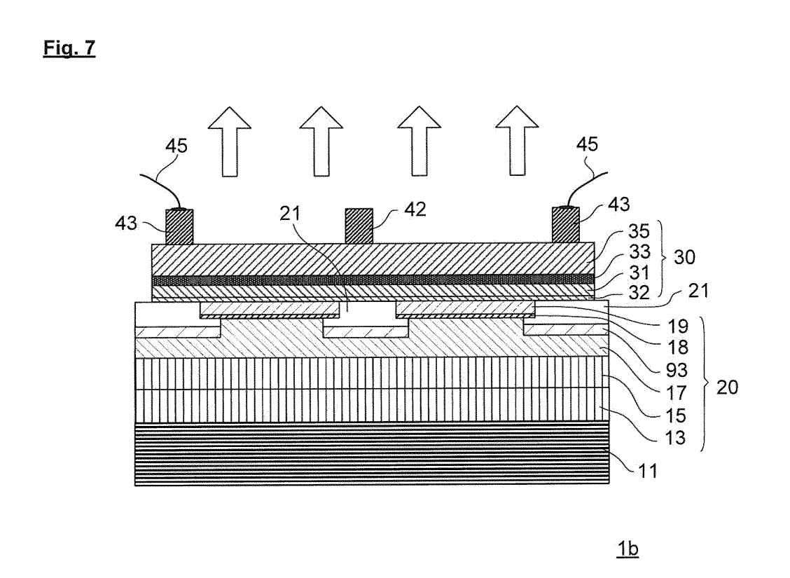

FIG. 7 is a sectional view schematically showing one example of a configuration of a semiconductor light-emitting element 1b according to another embodiment. In this configuration, at the positions opposite to the n-side electrodes (42, 43) in the first direction, the reflective electrode 19 is not formed but the insulating layer 21 is formed. On the bottom face of the insulating layer 21 (plane on the side of the support substrate 11), the reflective film 18 is formed.

In forming the reflective electrode 95 (corresponding to the reflective electrode 19 in FIG. 7) in the conventional semiconductor light-emitting element 90 shown in FIG. 10, the semiconductor light-emitting element 1b is obtained by vapor depositing the electrode material, and then forming the conductive material (second conductive layer 18a) constituting the first protective layer 18 without previously conducting an annealing step, and then conducting an annealing treatment.

Also in the semiconductor light-emitting element 1b shown in FIG. 7, formation of voids between the reflective electrode 19 and the semiconductor layer 30, and between the reflective electrode 19 and the first protective layer 18 is suppressed, so that higher light extraction efficiency is realized in comparison with the conventional semiconductor light-emitting element 90.

<2> All of the semiconductor light-emitting elements (1, 1a, 1b) according to the aforementioned respective embodiments are designed on the assumption that the light extraction surface is n-side, and the opposite side is p-side. The present invention, however, may be realized by a configuration in which the n-side and the p-side are perfectly inversed.

<3> In the above embodiment, as the semiconductor light-emitting elements (1, 1a, 1b), a light-emitting element comprising a nitride semiconductor was adopted for explanation. However, the configuration of the present invention can also be applied to a light-emitting element formed of other semiconductors.

<4> In the semiconductor light-emitting elements (1, 1a, 1b) according to the aforementioned respective embodiments, the insulating layer 21 is formed at the positions opposite to the n-side electrodes (42, 43) in the first direction (the direction perpendicular to the substrate plane) for the purpose of extending the current flowing in the active layer 33 in the horizontal direction. In the present invention, however, the insulating layer 21 is not necessarily provided. From the viewpoint of increasing the light extraction efficiency for the same amount of current, the insulating layer 21 is preferably formed.

<5> In the aforementioned respective embodiments, description was made for the case where the n-side electrodes (42, 43) and the reflective electrode 19 constituting the p-side electrode provided in the semiconductor light-emitting element show a so-called “vertical structure”, in which they are arranged spaced from each other in the direction perpendicular to the plane of the support substrate 11 with the semiconductor layer 30 interposed therebetween. The present invention, however, can also be applied to the case where the n-side electrode and the p-side electrode show a so-called “horizontal structure” in which they are arranged in the same direction with respect to the semiconductor layer 30. In this case, the step of bonding the support substrate 11 to the growth substrate 61 (step S10), and the step of lifting off the growth substrate 61 (step S11) are not provided. That is, the semiconductor light-emitting element is formed on the upper layer of the growth substrate 61.

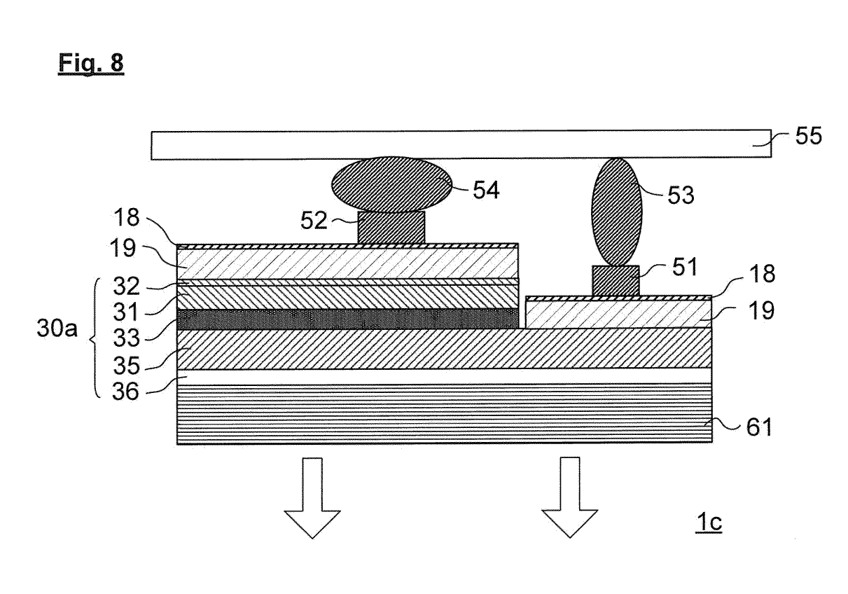

FIG. 8 is a schematic sectional view of a semiconductor light-emitting element 1c of another embodiment. The material identical to that in the first embodiment is denoted by the same reference numeral, and detailed description thereof will be omitted. The arrow in FIG. 8 indicates the light extraction direction, which is opposite to the light extraction direction in the semiconductor light-emitting element 1 shown in FIG. 1.

The semiconductor light-emitting element 1c includes the growth substrate 61, a semiconductor layer 30a, the reflective electrode 19, the first protective layer 18, a feed terminal 51, and a feed terminal 52. The semiconductor layer 30a includes the p-type semiconductor layer 31, the p-type semiconductor layer 32, the active layer 33, the n-type semiconductor layer 35, and the undoped layer 36.

Also in this configuration, by vapor depositing the conductive material (first conductive layer 19a) constituting the reflective electrode 19, and vapor depositing the conductive material (second conductive layer 18a) constituting the first protective layer 18 without previously conducting an annealing treatment, and then conducting an annealing treatment as is the case with the aforementioned respective embodiments, formation of voids between the reflective electrode 19 and the semiconductor layer 30a, and between the reflective electrode 19 and the first protective layer 18 is prevented.

Hereinafter, a method of producing the semiconductor light-emitting element 1c shown in FIG. 8 will be described only in the points which are different from the first embodiment.

First, steps S1 to S3 are conducted in the same manner as in the first embodiment (see FIG. 2A).

(Step S14)

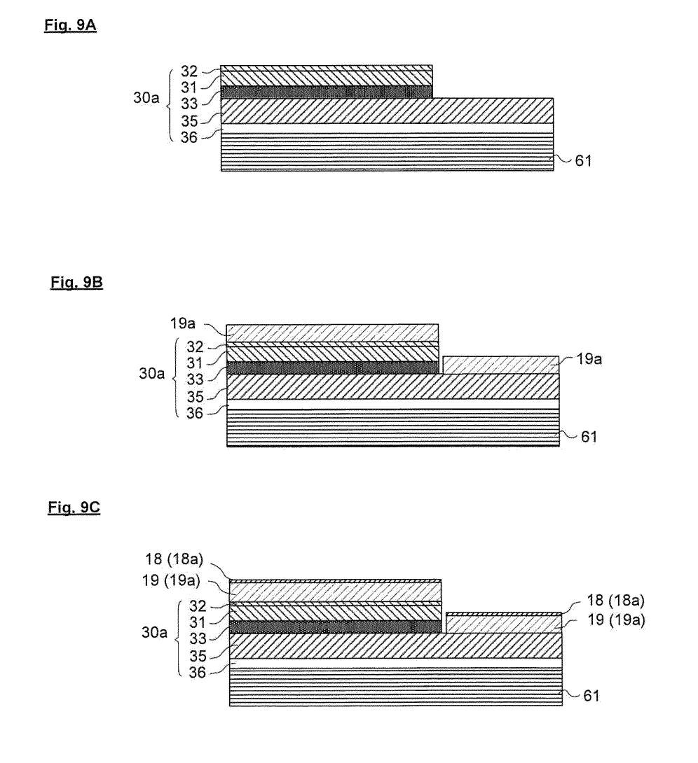

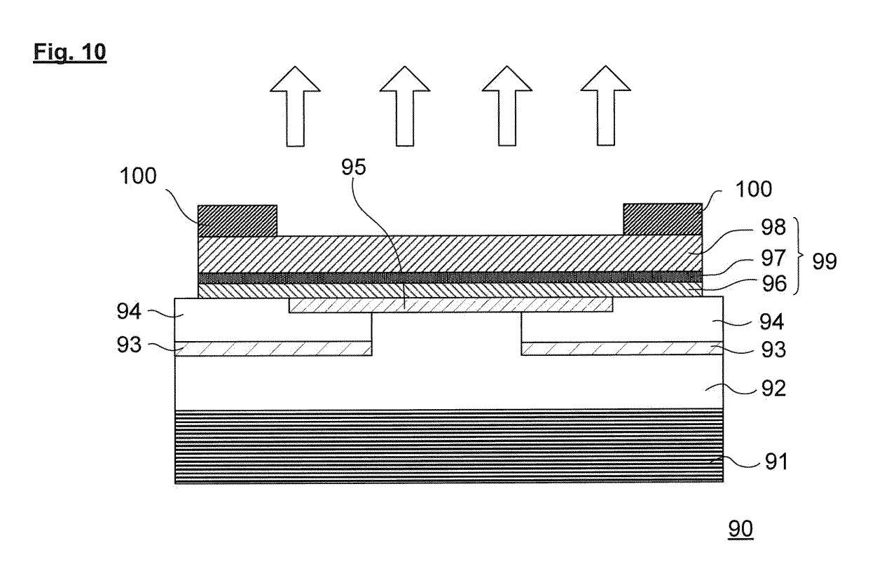

After step S3, as shown in FIG. 9A, the p-type semiconductor layer 32, the p-type semiconductor layer 31, and the active layer 33 are removed until the upper surface of the n-type semiconductor layer 35 is partly exposed by dry etching using an ICP device. In this step, the n-type semiconductor layer 35 may also be partly removed by etching.

(Step S15)

As shown in FIG. 9B, on the upper surface of the p-type semiconductor layer 32, and on the upper surface of the exposed n-type semiconductor layer 35, the conductive material (first conductive layer 19a) constituting the reflective electrode 19 is vapor deposited in the same manner as in step S4 of the first embodiment.

(Step S16)

Next, as shown in FIG. 9C, the conductive material (second conductive layer 18a) constituting the first protective layer 18 is vapor deposited as a thin film having a thickness of equal to or less than 7 nm on the whole upper surface of the first conductive layer 19a in the same manner as in step S5 of the first embodiment. Also at this time, this step is conducted without previously conducting an annealing step after conduction of step S15 as is the case with the first embodiment.

(Step S17)

In the same manner as in step S6 of the first embodiment, an annealing treatment using an RTA device or the like is conducted at 350° C. to 550° C. in a dry air atmosphere for 60 seconds to 300 seconds to form ohmic contact between the first conductive layer 19a and the p-type semiconductor layers (31, 32) and between the first conductive layer 19a and the n-type semiconductor layer 35. Through this step, the first conductive layer 19a functions as the reflective electrode 19, and the second conductive layer 18a turns into a conductive oxide layer (first protective layer 18).

Also in the configuration of the present embodiment, a previous annealing step is not conducted after vapor deposition of the first conductive layer 19a constituting the reflective electrode 19, but an annealing step is conducted in the state that the whole upper surface of the first conductive layer 19a is covered with the second conductive layer 18a (first protective layer 18) as is the case with the first embodiment, and therefore, formation of voids between the reflective electrode 19 and the semiconductor layer 30 is suppressed.

Further, since annealing is conducted after vapor depositing the second conductive layer 18a as a thin film in the same manner as in the first embodiment, formation of voids between the second conductive layer 18a (first protective layer 18) and the first conductive layer 19a (reflective electrode 19) is also prevented.

(Step S18)

Then on the upper surface of the first protective layer 18 on the reflective electrode 19 that is formed on the upper surface of the n-side semiconductor layer 35, the feed terminal 51 is formed, and on the upper surface of the first protective layer 18 on the reflective electrode 19 that is formed on the upper surface of the p-side semiconductor layer 32, the feed terminal 52 is formed. More concretely, after forming a conductive material film (for example, a material film comprising Cr having a thickness of 100 nm and Au having a thickness of 3 μm) that forms the feed terminals 51, 52 on the whole surface, the feed terminals 51, 52 are formed by lift-off. Then sintering at 250° C. is conducted in a nitrogen atmosphere for 1 minute.

Then by connecting the substrate 55 and the feed terminal 51 via a bonding electrode 53, and connecting the substrate 55 and the feed terminal 52 via a bonding electrode 54, the semiconductor light-emitting element 1c shown in FIG. 8 is formed.

<6> In the aforementioned first embodiment, at the position opposite to the n-side electrode 42 in the first direction (direction perpendicular to the plane of the support substrate 11), a reflective layer showing Schottky contact with the semiconductor layer 30 may be formed on the plane of the semiconductor layer 30 on the side of the support substrate 11. In this case, the insulating layer 21 may not be provided in the part opposite to the n-side electrode 42 in the first direction. Also in this case, the insulating layer 21 may be formed at the position opposite to the n-side electrode 43 in the first direction.

In this another embodiment, a plurality of reflective electrodes 19 are formed discretely at positions not opposite to the n-side electrode 42 in the first direction in such a manner that they are in contact with the plane of the semiconductor layer 30 on the side of the support substrate 11. The reflective layer is in contact with the area where the insulating layer 21 and the reflective electrode 19 are not formed in the plane of the semiconductor layer 30 on the side of the support substrate 11, and Schottky contact is formed in this plane. Further, the reflective layer has a larger thickness than the reflective electrode 19, and is formed to cover the reflective electrode 19 and first protective layer 18. The second protective layer 17 is formed to cover the upper surfaces of the reflective layer and the insulating layer 21 when the support substrate 11 is upside.

The reflective layer can be made of the same material as the material constituting the reflective electrode 19, and for example, Ag can be used. That is, in the configuration of the other embodiment, the first protective layer is formed on the upper surface of the reflective electrode 19, the reflective layer is formed on the upper surface of the first protective layer, and the second protective layer is formed on the upper surface of the reflective layer.

This semiconductor light-emitting element is also formed through step S4 to step S6 in the same manner as in the semiconductor light-emitting element 1 of the first embodiment, so that formation of voids between the reflective electrode 19 and the semiconductor layer 30, and between the reflective electrode 19 and the first protective layer 18 is prevented.

<7> In the aforementioned first embodiment, description was made on the assumption that the second protective layer 17 formed in step S8 has a multi-layered structure made up of the Ni layer 17a, the Ti layer 17b, and the Pt layer 17c. Among these, the Ti layer 17b and the Pt layer 17c are formed for the purpose of preventing diffusion of the material constituting the solder layer 15 formed in step S9. Therefore, any other material that prevents diffusion of the solder material can be employed without limited to the multi-layered structure of Ti/Pt.

The Ni layer 17a is formed for the purpose of preventing Ti from diffusing on the side of the reflective electrode 19 to deteriorate the reflectance. However, the semiconductor light-emitting element 1 including the second protective layer 17 not having the Ni layer 17a is also within the scope of the present invention.

<8> In the above embodiment, the material constituting the reflective electrode 19 (first conductive layer 19a) is formed of Ag, and the material constituting the first protective layer 18 (second conductive layer 18a) is formed of Ni. However, the method of the present invention is applicable to the case where the reflective electrode is made of a material other than Ag which is a conductive material having reflective function, and has a problem that the reflectance is deteriorated by formation of voids in the interface between the electrode and the semiconductor layer.

### REFERENCE SIGNS LIST

1 Inventive semiconductor light-emitting element
1a Inventive semiconductor light-emitting element
1b Inventive semiconductor light-emitting element
1c Inventive semiconductor light-emitting element
11 Support substrate
13 Solder layer
15 Solder layer
17 Second protective layer
17a Ni layer
17b Ti layer
17c Pt layer
18 First protective layer
18a Second conductive layer
19 Reflective electrode
19a First conductive layer
21 Insulating layer
30 Semiconductor layer
30a Semiconductor layer
31 p-type semiconductor layer
32 p-type semiconductor layer
33 Active layer
35 n-type semiconductor layer
36 Undoped layer
40 Epitaxial layer
42 n-side electrode
43 n-side electrode
45 Wire
51 Feed terminal
52 Feed terminal
53 Bonding electrode
54 Bonding electrode
55 Substrate
61 Growth substrate
90 Conventional semiconductor light-emitting element
91 Support substrate
92 Conductive layer
93 Reflective film
94 Insulating layer
95 Reflective electrode
96 p-type semiconductor layer
97 Active layer
98 n-type semiconductor layer
99 Semiconductor layer
100 n-side electrode
101 Void

1. A method for producing a semiconductor light-emitting element having a first semiconductor layer of n-type or p-type, a second semiconductor layer of a conductivity type different from a conductivity type of the first semiconductor layer, and an active layer formed between the first semiconductor layer and the second semiconductor layer, the method comprising:
a step (a) of preparing a substrate;
a step (b) of forming the first semiconductor layer, the light-emitting layer and the second semiconductor layer on the upper layer of the substrate in this order from below;
a step (c) of forming a first conductive layer constituting a reflective electrode on the upper layer of the second semiconductor layer;
a step (d) of forming a second conductive layer, without previously conducting annealing, constituting a first protective layer in a thickness of equal to or less than 7 nm on an upper surface of the first conductive layer after the step (c); and
a step (e) of conducting annealing after the step (d).

2. The method for producing a semiconductor light-emitting element according to claim 1, comprising a step (f) of forming, after the step (e), a conductive second protective layer on the upper layer of or directly on the second conductive layer.

3. The method for forming a semiconductor light-emitting element according to claim 1, wherein
the first conductive layer is made of a metal material containing Ag, and
the second conductive layer is made of a metal material containing Ni.

4. The method for forming a semiconductor light-emitting element according to claim 2, wherein
the first conductive layer is made of a metal material containing Ag, and
the second conductive layer is made of a metal material containing Ni.

5. A semiconductor light-emitting element having, on the upper layer of a substrate, a first semiconductor layer of n-type or p-type, a second semiconductor layer of a conductivity type different from a conductivity type of the first semiconductor layer, and an active layer formed between the first semiconductor layer and the second semiconductor layer, the semiconductor light-emitting element comprising:
a reflective electrode formed on a surface of a side opposite to a side where the active layer is formed among surfaces of the second semiconductor layer, and
a first protective layer formed on a surface of a side opposite to a side where the second semiconductor layer is formed among surfaces of the reflective electrode, the first protective layer having a thickness of equal to or less than 7 nm and containing a conductive oxide of a metal material different from a material of the reflective electrode.

6. The semiconductor light-emitting element according to claim 5, wherein
the reflective electrode is made of a metal material containing Ag, and
the first protective layer is a layer having an oxide of a metal material containing Ni.

7. The semiconductor light-emitting element according to claim 5, comprising a second protective layer which is formed on a surface of a side opposite to a side where the reflective electrode is formed among surfaces of the first protective layer, or at a position farther from the first protective layer than the surface, and which is made of a metal material different from a material of the reflective electrode.

8. The semiconductor light-emitting element according to claim 6, comprising a second protective layer which is formed on a surface of a side opposite to a side where the reflective electrode is formed among surfaces of the first protective layer, or at a position farther from the first protective layer than the surface, and which is made of a metal material different from a material of the reflective electrode.

9. The semiconductor light-emitting element according to claim 8, wherein the second protective layer has a multi-layered structure laminating a layer containing Ni, a layer containing Ti and a layer containing Pt.
